(19) United States
(12) Patent Application Publication
(10) Pub. No.: US 2012/0032271 A1
(43) Pub. Date: Feb. 9, 2012

(54) High density semiconductor inverter

(76) Inventors: Fabio Alessio Marino, (US); Paolo Menegoli, (US)

(21) Appl. No.: 12/925,535

(22) Filed: Oct. 25, 2010

Related U.S. Application Data
(60) Provisional application No. 61/401,127, filed on Aug. 9, 2010.

(51) Int. Cl. H01L 21/70; H01L 21/8238

(52) U.S. Cl. 257/369; 438/217; 257/E21.632; 257/E21.532

(57) ABSTRACT

A novel semiconductor inverter is presented. The semiconductor structure is simple and has a reduced number of semiconductor junctions. It offers the advantage of being very small in area, very fast and very efficient. The current conductivity from either of the two main terminals to the output terminal is controlled by the gate voltage by means of depleting and enhancing the areas underneath the gate oxide. The signal isolation is obtained mainly by the carrier depletion of the channel region. Having a reduced number of semiconductor junctions, the intrinsic current leakage can be very small. This inverter is the elementary component for latches, memory and logic elements based on this technology.

### RELATED APPLICATION DATA

The present application claims priority from U.S. Provisional Patent Application No. 61/401,127 for “High Density Semiconductor Inverter” filed on Aug. 9, 2010.

### BACKGROUND OF THE INVENTION

1. Field of the Invention

The present invention is in the field of semiconductor structures. The present invention further relates to semiconductor inverters and digital circuits. The implementation is not limited to a specific technology, and applies to either the invention as an individual component or to inclusion of the present invention within larger systems which may be combined into larger integrated circuits.

2. Brief Description of Related Art

The semiconductor inverter is one of the most important components for larger digital integrated circuits. The complementary CMOS components used in current integrated circuit process technologies have undergone a continuous shrinking of the silicon area needed for elementary components like the inverter, however being the inverter the most commonly utilized digital circuits from which many others have derived, the need to further improve on its general performance while reducing its cost is a necessity that poses a significant challenge.

Generally the most utilized prior art of CMOS digital inverters comprises an NMOS and a PMOS with drain terminals tied together to form the inverter output and the two gates terminals connected together to form the input controlling terminal of the inverter. When the voltage polarity at the input terminal is high, its output terminal voltage polarity is low and vice versa. The dynamic characteristics of the signal toggling are very important to establish the inverter's efficiency and speed.

Combinations of inverters have also been widely used for latch circuits, flip-flops and memory elements in general. Digital logic gates like NOR and NAND are extensions of the basic inverter structure.

Prior art examples of attempts to reduce the silicon area of inverter circuits include Bansal et al. (U.S. Pat. No. 4,467,518), Malhi (U.S. Pat. No. 4,555,843), Sundaresan (U.S. Pat. No. 4,628,589), Mizutani (U.S. Pat. No. 4,698,659), Itho (U.S. Pat. No. 5,192,705), Gardner et al. (U.S. Pat. No. 5,872,029). The general approach in the cited references is to stack a pmos device above an nmos transistor, both devices controlled by the same gate. The nmos device is formed in the substrate while the p-channel transistor is formed in poly-silicon. The gate is formed between the two complementary transistors in a sandwich like structure.

All these examples, described many years ago, never gained utilization in the industry for several reasons one of which is the relative weakness of the pmos transistor with respect to the more common conventional inverter structure offering poor performances in terms of speed and dissipation. In fact the pmos transistor in most of the cited cases was a thin film transistor and its conductivity was not very high. A second problem is the alignment of the pmos transistor to the gate.

Another interesting prior art attempt to achieve higher density for inverter circuit is described in Ismail et al. (U.S. Pat. No. 5,808,344). In this case although the gate is still in common between the two transistors, it is not physically formed between the pmos and the nmos. The structure is shaped like a cross formed by the p-regions and the n-regions with the gate at the center of the cross. However the intrinsic structure of this approach limits the voltage applied to the inverter to be less than the forward bias voltage of the junction (0.6V).

It is therefore a purpose of the present invention to describe a novel CMOS structure of a semiconductor inverter that offers the advantage of much higher density reducing silicon area and cost combined with improved performances in terms of speed and power dissipation.

### SUMMARY OF THE INVENTION

The present invention describes an inverter whose operation is based on achieving signal isolation by controlling the depletion region under the gate area and exploiting the thickness of the material layer under said gate oxide.

In order to better grasp this concept, let us consider the structure illustrated in FIG. 2 in the case in which the n-terminal 19 is connected to ground and the p-terminal 14 is connected to the supply voltage V_{DD}. In such situation, when the voltage of the gate terminal 12 goes to 0V, the depletion region in the p-substrate 15 under the gate-oxide widens. If the thickness t_{S} of the metal layer 17 is thin enough, for V_{G}=Vₜₚ (threshold voltage) the depletion region width x_{d} is greater than t_{S}, and the output terminal 17 is therefore isolated from the p-terminal 14.

On the other hand, at the same time, electrons accumulate under the gate oxide in the n-side region 18. Consequently, the metallic terminal 17, whose terminal represents the output terminal of the inverter, results in conduction with the n-terminal 19 and the voltage of the output terminal 17 goes to 0V. Increasing the gate voltage, the exact opposite occurs: holes start to accumulate under the gate oxide on the p-side 15 and the n-substrate 18 depletes. Consequently the output terminal 17 voltage toggles to the supply voltage V_{DD}.

Therefore the illustrated FET structure behaves as a double switch connecting the output terminal 17 to the n- or to the p- terminals, depending on the voltage applied to the gate terminal 12.

In order to increase the isolation of the output terminal 17 from the n-terminal 19 when the gate 12 is at zero volt and the isolation of the output terminal 17 from the p-terminal 14 when the gate 12 is at the supply voltage, the metal region 17 under the gate can be substituted with two semiconductor regions, p-type doped the first one and n-type doped the second one, as illustrated in FIG. 3. In this case, the output terminal is coupled to a pad in the third dimension, which short-circuits these two semiconductor regions. In this configuration, when the voltage of the gate 22 is at zero volt the isolation of the output terminal from the n-terminal 30 is enhanced by the depletion of the added n-region 28 under the gate oxide 23. Vice-versa the opposite occurs when the gate 23 is brought to the supply voltage.

The same behavior can be obtained if the two side regions 25 and 29 are made in metal as illustrated in FIG. 4. In this embodiment, the two metal regions 35 and 39 can be done with the same metal or different ones, depending on the process available.

To increase the isolation of the side terminals from the output terminal, it is possible to substitute the gate with two regions, each one with a material of different working function as illustrated in FIG. 5. This can be achieved, using two different metals or a semiconductor layer with two different doping.

Another means of increasing the electrical isolation of the side terminals from the output terminal is to increase the oxide thickness in the central part of the device, as illustrated in FIG. 6. This must be done in the case in which the supply voltage used can lead to the formation of an n channel in the p-region 57 and/or a p-channel in the n-region 58, effectively creating conduction with the wrong terminal.

Another way to obtain the similar results consists in creating, in the center of the device, between the gate oxide and the box oxide, two additional regions heavily doped (or two different metals), as illustrated in FIG. 7. The same result can be obtained substituting the regions 69 and 71 with only one metal region. In this case, the region 72 and region 68 can be also doped in the opposite way with respect to the one illustrated in FIG. 7: region 72 can be a p-doped region, whereas region 68 can be a n-doped region.

We can also add other doped regions as illustrated in FIG. 8 and FIG. 9. Different possible variations can be obtained mixing the different approaches illustrated.

Furthermore, independently from the embodiment, the BOX oxide region under the central metal/semiconductor layer can be substituted with semiconductor doped in an appropriate way in order to guarantee the right functionality of the device.

The present invention can be realized in SOI (Semiconductor On Insulator) or CMOS bulk technology, and the side regions can have the same depth of the central metal/semiconductor layer.

In the case of CMOS bulk process technology, for example, the process steps required to build the structure of FIG. 6, which represents the preferred embodiment of the invention, can be summarized as follows. Starting from a p-doped (boron doped) wafer, an n-well is obtained with an n-type (arsenic or phosphor) implant. Thereafter, two more wells, one n-type and one p-type, are created in the substrate and in the previously described n-well, respectively. These two wells will form regions 59 and 56 in the structure of FIG. 6. A silicon etching and an oxide deposition will follow in order to form the BOX oxide region 51.

Regions 57 and 59 can be then grown on the top of region 51, using a silicon epitaxial growth technique followed by two doping implants. The gate oxide can be successively formed with thermal growth techniques. A small bump is created above the gate oxide layer 54, with a deposition and with an oxide etch process step. Thereafter, on the top of the dielectric layer 54 a poly-silicon layer is deposited, which will be doped partially with boron and partially with arsenic (or phosphor) impurities in order to obtain regions 61 and 53, respectively. These two regions will be then short-circuited with a metal deposition.

Successively contacts 55 and 60 can be formed using two more doping implants and one metal deposition. These two heavily doped regions and their respective metal contacts can be placed laterally or elsewhere.

It is important to notice that under the two contacts 55 and 60 of FIG. 6, heavily doped regions must be formed in order to reduce the contacts resistivity. These two regions have been omitted in all the drawing for simplicity, but their presence is obvious to a person skilled in the art.

It is therefore an object of the invention to increase the packing density and to reduce the device wiring capacitance by adding logic functionality to the structure without adding substantially to the area. It is a further object of the invention to speed up the velocity by reducing the number of junctions and eliminating the parasitic body diodes.

As is clear to those skilled in the art, this basic system can be implemented in many specific ways, and the above descriptions are not meant to designate a specific implementation.

### BRIEF DESCRIPTIONS OF THE DRAWINGS

The features, objects, and advantages of the present invention will become apparent upon consideration of the following detailed description of the invention when read in conjunction with the drawing in which:

FIG. 1 is a cross section view of a conventional inverter (prior art).

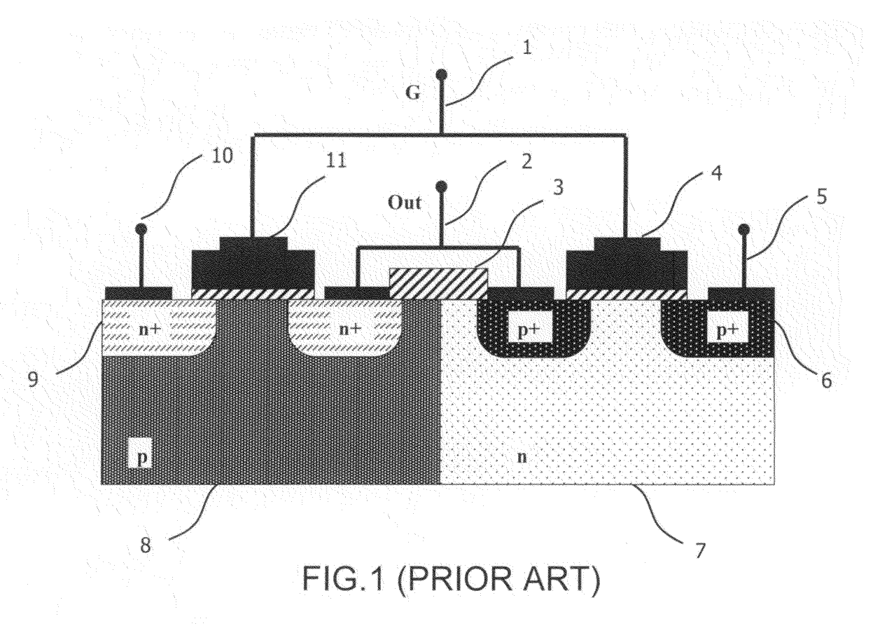

FIG. 2 is a cross section view of a first embodiment of the invention.

FIG. 3 is a cross section view of a second embodiment of the invention.

FIG. 4 is a cross section view of a third embodiment of the invention.

FIG. 5 is a cross section view of a fourth embodiment of the invention.

FIG. 6 is a cross section view of a preferred embodiment of the invention.

FIG. 7 is a cross section view of a sixth embodiment of the invention.

FIG. 8 is a cross section view of a seventh embodiment of the invention.

FIG. 9 is a cross section view of an eighth embodiment of the invention.

FIG. 10 shows the simulation results of the preferred embodiment of the invention compared with the simulation results obtained with a standard CMOS inverter.

### DETAILED DESCRIPTION OF SPECIFIC EMBODIMENTS

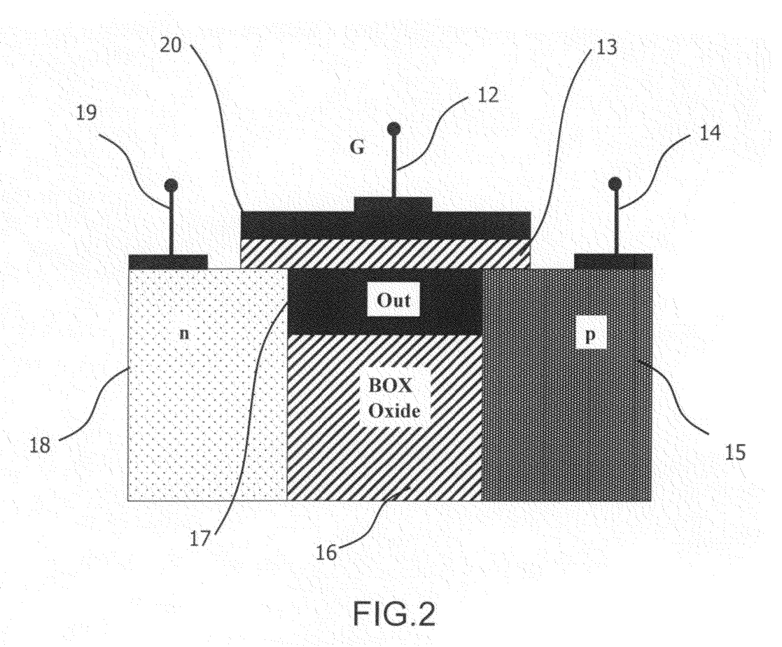

### A FIG. 2

FIG. 2 is showing the cross-section view of the first embodiment of the invention. The n-type region 18 and the metal region 17 define an n-type transistor. The p-type region 15 and the metal region 17 define a p-type transistor. The region 18 corresponds to the source of the n-type transistor. The region 15 corresponds to the source of p-type transistor. The metal region 17 corresponds to the drain of both transistors and it is the output terminal of the inverter structure. The gate electrode 12, which may be built in poly-silicon or metal, forms the gate of both transistors. The output of the inverter is coupled to a pad contacting the metal layer 17.

A box oxide 16 is present under the metal region 17 to electrically isolate the source of the two transistors. Above the metal region 17 an oxide layer 13 is present and it extends over the metal region, above the regions 18 and 15. Above the oxide layer 13, the gate layer 20 is present.

In order to understand this concept, let us consider the structure illustrated in FIG. 2 in the case in which the n-terminal 19 is connected to ground and the p-terminal 14 is connected to the supply voltage V_{DD}. In such situation, when the voltage of the gate terminal 12 goes to 0V, the depletion region in the p-substrate 15 under the gate-oxide widens. If the thickness t_{S} of the metal layer 17 is thin enough, for V_{G}=Vₜₚ (threshold voltage) the depletion region width x_{d} is greater than t_{S}, and the output terminal 17 is therefore isolated from the p-terminal 14.

On the other hand, at the same time, electrons accumulate under the gate oxide in the n-side region 18. Consequently, the metallic terminal 17, whose terminal represents the output terminal of the inverter, results in conduction with the n-terminal 19 and the voltage of the output terminal 17 goes to 0V. Increasing the gate voltage, the exact opposite occurs: holes start to accumulate under the gate oxide on the p-side 15 and the n-substrate 18 depletes. Consequently the output terminal 17 voltage toggles to the supply voltage V_{DD}.

Therefore the illustrated FET structure behaves as a double switch connecting the output terminal 17 to the n- or to the p- terminals, depending on the voltage applied to the gate terminal 12.

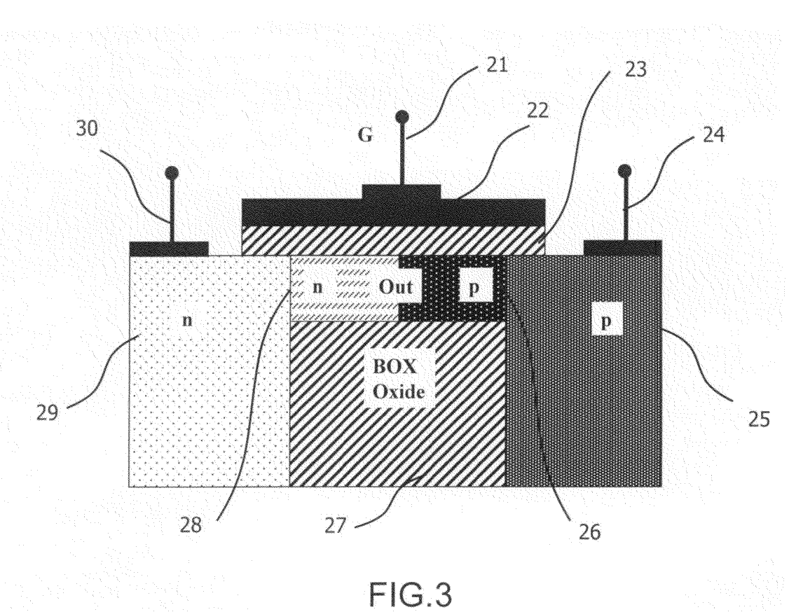

### B FIG. 3

The drawing of FIG. 3 shows a cross section view of the second embodiment of the semiconductor inverter. The n-type regions 29 and 28 define a n type transistor. The p-type regions 26 and 25 define a p type transistor. Regions 29 and 28 correspond to the source and drain, respectively, of the n-type transistor. Regions 25 and 26 correspond to the source and drain, respectively, of the p-type transistor. The gate electrode 22 which may be built in poly-silicon or in metal, forms the gate of both transistors. The output of the inverter is coupled in the third dimension to a pad that short-circuits regions 26 and 28. Under regions 26 and 28 a box oxide 27 is present in order to electrically isolate the source of the two transistors. Above these two regions an oxide layer 23 is present, which can be extended (or not) over the two regions 26 and 28, above the regions 25 and 29. Above the oxide layer, the gate layer 22 is present.

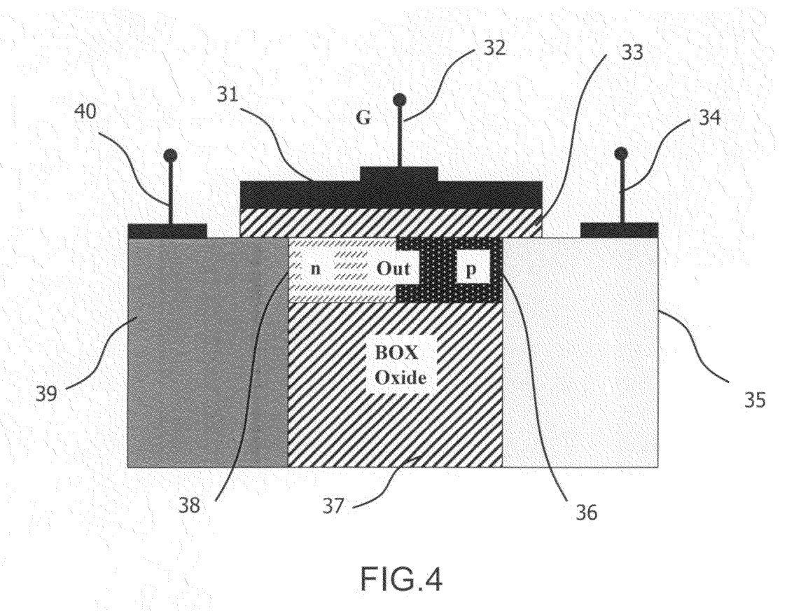

### C FIG. 4

FIG. 4 is depicting the cross-section view of a third embodiment of the invention. This structure is similar to FIG. 3, with the exception that the semiconductor regions 29 and 25 of FIG. 3 are replaced with metal regions. These regions can be made of the same materials or not.

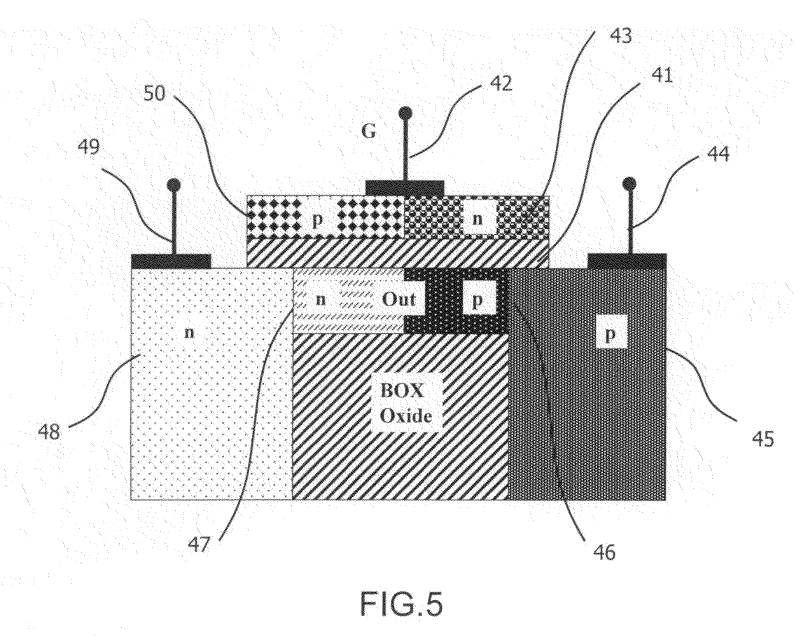

### D FIG. 5

FIG. 5 is showing the cross-section view of a fourth embodiment of the invention. This structure is similar to one depicted in FIG. 3, with the exception that the gate layer 23 is replaced with two regions with different working functions. These two regions can be made in semiconductor or metal. These substitutions can be made in order to decrease the leakage current in the device.

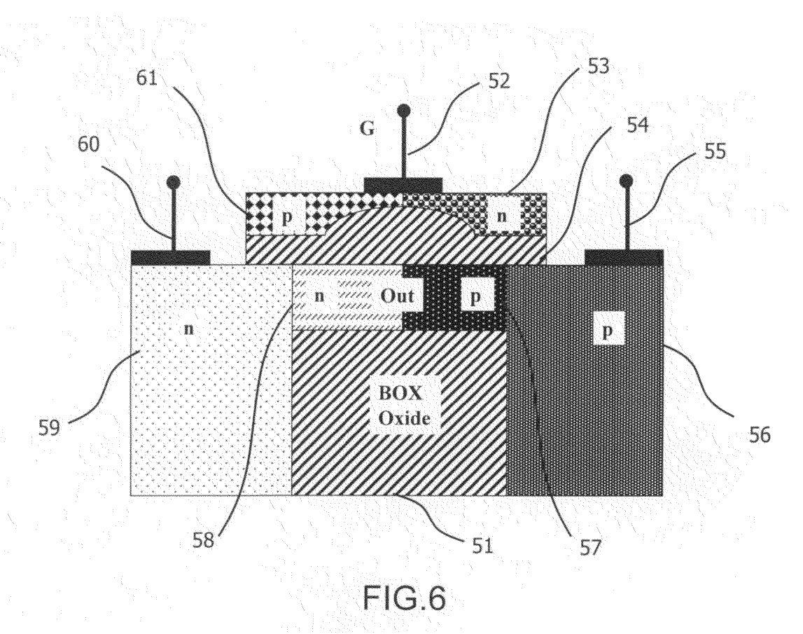

### E FIG. 6

FIG. 6 is referring to the cross-section view of the preferred embodiment of the invention. This structure is similar to the one of FIG. 5, with the exception that in the center region of the device, the gate oxide 54 is thicker than in the side regions. This prevents the creation of a channel under the gate oxide that can generate conduction between the two side regions 59 and 56.

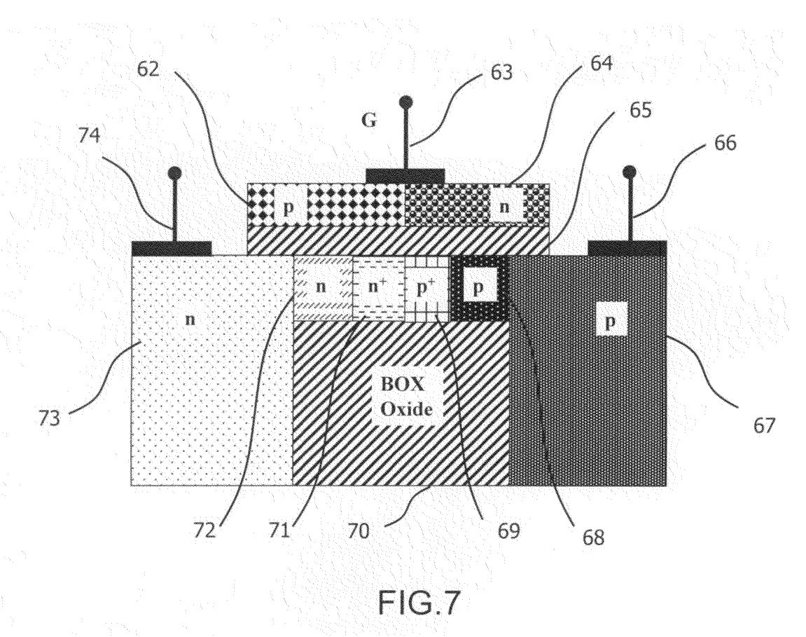

### F FIG. 7

FIG. 7 is showing the cross-section view of a sixth embodiment of the invention. This structure is similar to the one showed in FIG. 5, with the exception that in the center region of the device, under the gate oxide 65, two heavily doped semiconductor regions 71 and 69 are added. These regions will prevent the creation of a channel under the gate oxide that can generate conduction between the two side regions 73 and 67. The two added regions can be also done with two different metals or replaced by only one metal region. In this case, the region 72 can be doped of opposite type doping with respect to the side regions 73, and region 68 can be doped of opposite type doping with respect to the side region 67.

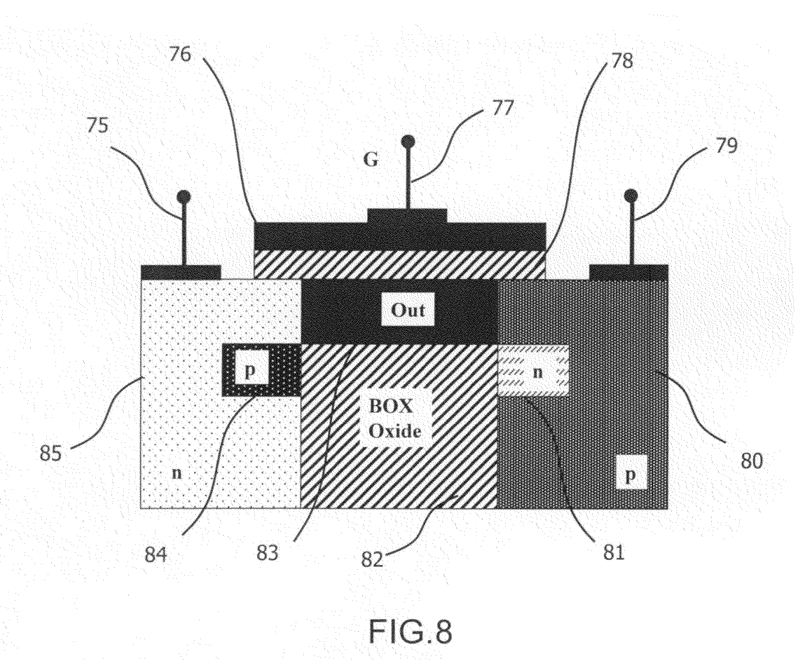

### G FIG. 8

FIG. 8 is showing the cross-section view of a seventh embodiment of the invention. This structure is similar to the one of FIG. 2, with the exception that the electrical isolation of the metal layer from the side terminals is enhanced adding two additional regions 81 and 84.

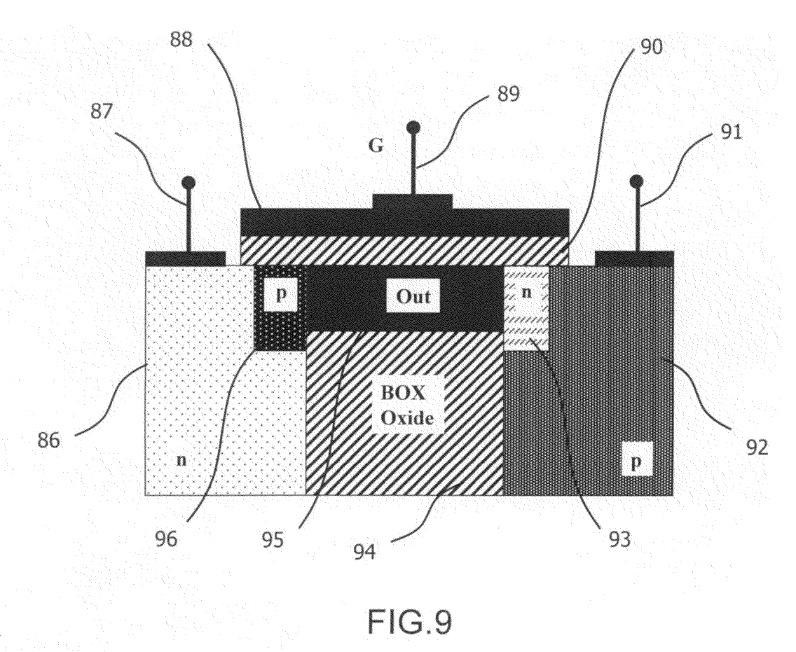

### H FIG. 9

FIG. 9 is depicting the cross-section view of another embodiment of the invention. This structure is similar to the one of FIG. 8, with the exception that the two additional regions 93 and 96 are in contact with the gate oxide 90.

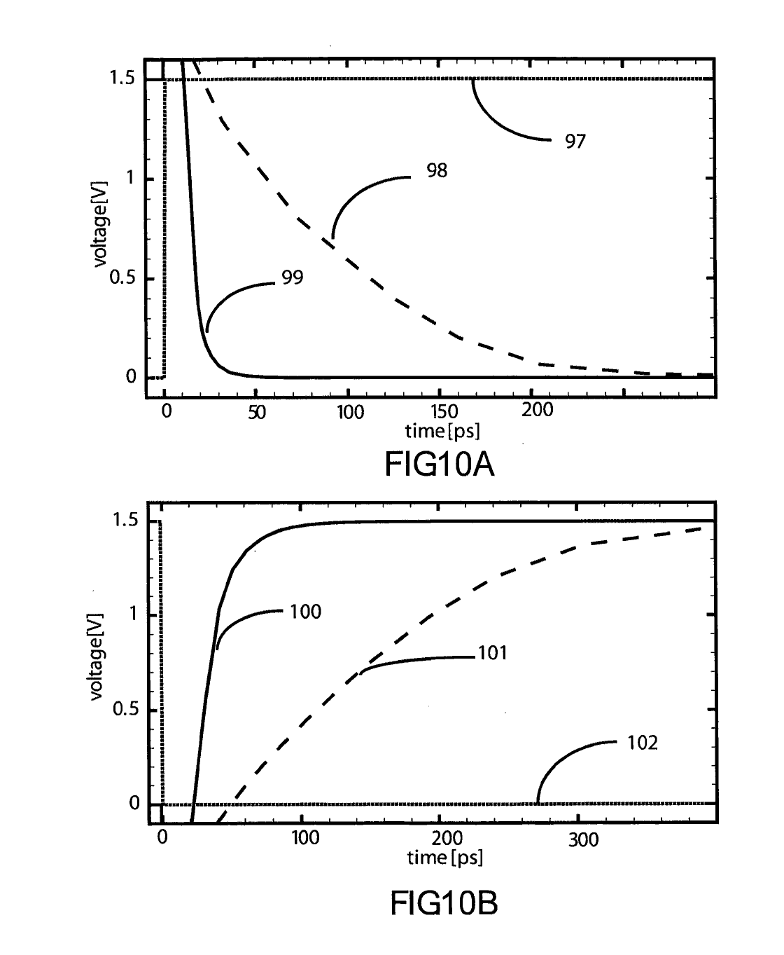

### I FIG. 10

FIG. 10 is showing the simulation results of the preferred embodiment of the invention compared with the simulation results obtained with a standard CMOS inverter. Waveforms 97 and 102 represent the digital signals applied to the gate of the inverter, in the case where the input signal is switching from low state to high state and in the case where the input signal is switching from high state to low state, respectively. Waveforms 98 and 101 represent the output of a conventional CMOS inverter. Waveforms 99 and 100 are the output of the presented invention. As it can be seen the presented invention greatly improves the performances of the inverter.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed:

1) A method for generating an efficient semiconductor field effect device comprising:
forming a first field effect transistor of a first conductivity type;
forming a second field effect transistor of a second conductivity type, and
forming a region below the drains of said first and second field effect transistors that isolates the source of said first field effect transistor from the source of said second field effect transistor;
wherein said source of said first field effect transistor is coupled to a first supply voltage, and said source of said second field effect transistor is coupled to a second supply voltage;
wherein said drains of said first and second field effect transistors are formed in a single drain region, and are coupled to an output terminal of said field effect device, and
wherein the gates of said first and second field effect transistors are formed in a single gate region, and are coupled to a gate terminal to control said field effect device by generating depletion and enhancement regions to modulate the conductivity of the semiconductor region under the gate dielectric, by means of coupling one or the other of said sources of said first and second field effect transistors to said output terminal of said field effect device depending on the voltage of said gate terminal.

2) The method according to claim 1 wherein said regions of said first and second field effect transistors are made from at least one of the materials belonging to the group comprising of semiconductor, dielectric and metal.

3) The method according to claim 1 wherein at least one of said drain and gate regions is divided in two regions of two different materials or conductivity types placed in physical contact and directly coupled together.

4) The method according to claim 1 wherein said field effect device is comprising n-well and p-well regions below said first and second field effect transistors.

5) The method according to claim 1 wherein said field effect device is formed within silicon on insulator substrate.

6) The method according to claim 1 wherein at least one of said first and second field effect transistors has one or less rectifying junction placed in physical contact with the dielectric under said gate region, and
wherein said rectifying junction is a p-n semiconductor junction or a metal-semiconductor non-ohmic junction.

7) An efficient semiconductor field effect device structure comprising:
a first field effect transistor of a first conductivity type comprising a first region coupled to a first supply voltage and a second region coupled to an output terminal of said field effect device;
a second field effect transistor of a second conductivity type comprising a third region coupled to said output terminal of said field effect device and a fourth region coupled to a second supply voltage;
a fifth region below said second and third regions that isolates said first region from said fourth region;
a dielectric region above said second and third regions, that extends partially beyond said second and third regions;
a gate above said dielectric region coupled to a gate terminal to control said field effect device by generating depletion and enhancement regions and to modulate the conductivity of the semiconductor region under said dielectric region, by means of coupling one or the other of said first and fourth regions to said output terminal depending on the voltage of said gate terminal;
wherein said first and fourth regions are spaced apart from each other.

8) The structure of claim 7 wherein said second and third regions are replaced by a single central region.

9) The structure of claim 7 wherein said second and third regions are replaced by three regions;
wherein two of said three regions are lateral and of opposite conductivity type semiconductor materials, and
wherein the third of said three regions comprises a metal region.

10) The structure of claim 7 wherein said regions of said first and second field effect transistors are made from at least one of the materials belonging to the group comprising of semiconductor, dielectric and metal.

11) The structure of claim 7 wherein said fifth region below said second and third regions is done in semiconductor material properly doped in order to guarantee the isolation between said first region and said fourth region.

12) The structure of claim 7 wherein said first and fourth regions are of opposite conductivity type semiconductor materials, and each one of said first and fourth regions comprises a region of opposite conductivity type formed laterally to at least one of said fifth region and said third region.

13) The structure of claim 7 wherein said semiconductor field effect device is comprising n-well and p-well regions below said first and second field effect transistors.

14) The structure of claim 7 wherein said semiconductor field effect device is formed within silicon on insulator substrate.

15) The structure of claim 7 wherein at least one of said first and second field effect transistors has one or less rectifying junction placed in physical contact with said dielectric region under the said gate, and
wherein said rectifying junction is a p-n semiconductor junction or a metal-semiconductor non-ohmic junction.
